(19) United States
(12) Patent Application Publication
(10) Pub. No.: US 2024/0126217 A1
(43) Pub. Date: Apr. 18, 2024

(54) FLEXIBLE ELECTRONIC SYSTEM FOR FLEXIBLE WEARABLE DEVICES AND OTHER ELECTRONIC DEVICES

(71) Applicant: Meta Platforms Technologies, LLC, Menlo Park, CA (US)

(72) Inventors: Michael Tawfik Khbeis, Federal Way, WA (US); Shantonu Biswas, Lynnwood, WA (US); Lichuan Chen, Bellevue, WA (US); Omar Awartani, Redmond, WA (US); Benjamin Cook, Woodinville, WA (US); Amirhossein Hajiagha Memar, Woodinville, WA (US)

(21) Appl. No.: 18/378,810

(22) Filed: Oct. 11, 2023

Related U.S. Application Data
(60) Provisional application No. 63/415,623, filed on Oct. 12, 2022.
(60) Provisional application No. 63/462,829, filed on Apr. 28, 2023.

(51) Int. Cl. G04G 17/08; G04G 17/02; G06F 1/16

(52) U.S. Cl. CPC G04G 17/08; G04G 17/02; G06F 1/163; G06F 1/1635; G06F 1/1652

(57) ABSTRACT

A flexible electronic system comprises a flexible substrate comprising an interlayer elastomer dielectric and a plurality of rigid components disposed within the flexible substrate. The flexible electronic system may further comprise a high-density interconnect region comprising one or more routing layers. In examples, the flexible electronic system may further comprise a flexible barrier material encapsulating the flexible electronic system. In some examples the flexible electronic system and the high-density interconnect region may further comprise a plurality of routing layers and one or more through-vias. Each through-via may couple at least one of two rigid components, two routing layers, or a rigid component and a routing layer. In examples, at least some of the routing layers may comprise conductive traces.

### CROSS-REFERENCE TO RELATED APPLICATIONS

This application claims priority to U.S. Provisional Application No. 63/415,623, filed Oct. 12, 2022, which is incorporated herein by reference, and also claims priority to U.S. Provisional Application No. 63/462,829, which was filed on Apr. 28, 2023, which is also incorporated herein by reference. Any or all of the features, components, and techniques described in both of these provisional applications may be used in combination with or in lieu of any of the features described in this application with respect to flexible electronic systems.

### BACKGROUND

Wearable devices, such as smart watches, generally cluster all of the electronics, power supplies (e.g., batteries, capacitors, etc.), communications devices, and sensors into a rigid capsule or a head case, while the band is typically free of electronic components and used simply to secure the wearable device to the user. This non-use of bands leaves approximately 50% of a smart watch or other wearable device volume underutilized.

### BRIEF DESCRIPTION OF THE DRAWINGS

The detailed description is described with reference to the accompanying figures. In the figures, the left-most digit(s) of a reference number identifies the figure in which the reference number first appears. The use of the same reference numbers in different figures indicates similar or identical components or features.

FIGS. 1A-1C schematically illustrate example flexible electronic systems, in accordance with examples of the present disclosure.

FIGS. 2A-2D schematically illustrate examples of wearable electronic devices that include one or more flexible electronic systems, in accordance with examples of the present disclosure.

FIG. 3 illustrates a flow diagram of an example method of forming a flexible electronic system, in accordance with an example of the present disclosure.

### DETAILED DESCRIPTION

### Overview

Human sensing applications (e.g., electromyography (EMG), photoplethysmography (PPG), etc.) are better served by strategic placement and often need to maintain contact-proximity to the wearer.

Recent efforts to build functional, stretchable EMG bands have been plagued with manufacturing and materials challenges, such as elastomer molding around “rigid island” pucks that tend to suffer delamination at the rigid-soft interface. In industry, the packaging industry, e.g., outsourced semiconductor assembly and test (OSAT) parties, are driving toward panel-level manufacturing for multi-chip module (MCM) and system-in-package (SiP) applications. Panel-level packaging (PLP) is typically geared toward rigid packaging (e.g., molding, laminates) and as a result, the outputs are typically rigid modules. Alternatively, the Flexible Hybrid Electronics (FHE) efforts have been focused on flexible and/or stretchable systems, that use printed composite ink traces and conducive adhesives to assemble commercial-off-the-shelf (COTS) components. These systems do not offer compact integration of components and often stretchable traces suffer from substantial electrical losses as a function of strain.

Additionally, haptic glove systems add complexity to panel-level manufacturing for MCM and SiP applications as haptic glove systems need the flexibility and/or stretchability of other wearable systems but also need multi-modal sensing and actuator technologies.

This disclosure is directed to wearable systems that are fully, or at least partially, flexible and/or stretchable, such as watches, fitness bands, or other wrist wearables, head-mounted devices, rings, haptic gloves, other articles of clothing, or any other wearable system that includes a portion that is flexible and/or stretchable. While the techniques, methods, components, systems, and architectures described herein are described primarily with respect to watches, gloves, and other wearable devices, the techniques, methods, components, systems, and architecture described herein are also applicable to other electronic devices.

For example, the techniques, methods, components, systems, and architecture described herein use panel-level manufacturing to enable dense integration of electronics, power supplies (e.g., batteries, capacitors, etc.), communication devices, sensors, actuators, shielding, and/or antennas in large, flexible, and/or stretchable wearable form factors. By blending semiconductor processes, panel (or wafer)-scale packaging, embedded component packaging (ECP), flexible hybrid electronics (FRE), novel materials integration, and/or even micro-fluidic soft lithography techniques, the techniques described herein can produce electronic systems that are embedded or integrated into soft, flexible, and/or stretchable wearable systems at mass manufacture scale.

The techniques, methods, components, systems, and architecture described herein reduce currently unused or underused space of electronic devices and enable construction of electronic devices that are more densely populated, powerful, flexible, light weight, and/or functional than conventional devices that rely primarily or exclusively on rigid islands of electronics such as those that are often found in wearable electronics. Typically, rigid islands contain the rigidly immobilized components (e.g., silicon devices and surface mount devices (SMDs)) and are interconnected by flexible-printed circuits (FPCs). In this configuration, failures often occur at the interface between the rigid and flex sub-assemblies.

In examples of the techniques described herein, components are embedded in a flexible and/or stretchable interlayer elastomer dielectric, referred to as the “flexible substrate.” By chemical manipulation (e.g., inhibited silicones), the bonding of stretchable elastomers to rigid components (integrated circuits (ICs), surface mount devices (SMDs), and FPC regions may be enhanced, thereby circumventing common rigid-soft interfacial failures. This substrate also contains flexible and/or stretchable traces for interconnections between the components (e.g., individual rigid or flexible components), as well as between other islands, e.g., islands made up of a flexible substrate bonded to rigid components.

Rigid island regions may be formed by selectively disposing flexible printed circuit (FPC) materials (e.g., polyimide/copper, Ajinomoto build-up film (ABF)/Cu, or other flex circuit materials). In examples, the rigid island regions may be referred to as high-density interconnects (HDIs) that enable fine pitch (or trace/space) line widths for electrical signal routing for chip-to-chip and SMD connections. The HDI is generally comprised of one or more routing layers that may be vertically connected with conventional (e.g., plated copper) or unconventional conductive materials (e.g., liquid metals (LM), LM-composite inks, composites, conductive adhesives or similar materials) in the form of through-vias. Assembly of the HDIs may be made using conventional (e.g., solder) or unconventional (e.g., gold-to-gold interconnect (GGI), thermos-sonic bonding, adhesive bonding). Stacking of HDI layers above and below the stretchable substrate can be extended for one layer to a plurality of layers (e.g., 2, 3, 4, . . . 10, . . . N) as needed to add system-level component densification.

In some examples, the flexible electronic systems may include fluidic channels in the substrate and/or HDI layers for routing of pneumatic or other working media (e.g., water, oil, etc.) that conduct signals for haptic actuation and/or sensing. For instance, for system-in-glove (SiG) arrangements (e.g., uses of the flexible electronic systems in a glove such as a haptic glove), the flexible electronic systems may include microfluidic channels in both substrate and HDI layers for routing of working media that conduct signals for haptic actuation and sensing. Microelectromechanical systems (MEMS) sensors and actuators may be embedded in elastomeric substrates and can leverage HDI for robust assembly and interfaces. In general, this scenario may be described as creating an electromechanical substrate that is not only a printed circuit board (PCB) or a flexible printed circuit (FPC) for electrical signal routing, but also a substrate for routing mechanical signals (inputs and/or outputs) as well.

In examples, both the substrate and HDI layers may be leveraged as smart interposers. This may include the incorporation of active circuitry, for example, the use of thin-film transistors (TFT) or similar elements for signal processing, networking, power management or other “smart substrate” functions. Furthermore, sensing may be directly embedded into the substrate for closed loops of MEMS sensors and actuators. For example, electrical structures such as variable capacitor structures can be used for pressure sensing, or thermocouple materials can be deposited to measure flow in pneumatic actuation systems.

### Example Electronic Device(s)

In some examples, the flexible electronic systems described herein may be used in devices, such as, but not limited to, a wrist wearable device (e.g., a smartwatch, fitness band, bracelet, controller, etc.), a hand wearable device (e.g., haptic glove, ring, etc.), a head-mounted device (e.g., glasses, an electronic headset device, a head, a headband, etc.), or other wearable devices. Examples of wearable devices may include devices that can execute mobile applications, mobile operating system(s), output media content, provide connectivity to one or more other devices (e.g., via Wi-Fi, mobile networks, Bluetooth®, global positioning system (GPS), etc.), monitor health or fitness (and associated metrics) of a user, among other operations. The wearable devices described herein may also include a display and touchscreen interface that allows users to view, create, consume, and share media content. Furthermore, the wearable device described herein may be connected to one or more other devices and may be configured to control one or more functions of the other devices based in part on user input received via the wearable device.

Additionally, or alternatively, the flexible electronic systems described herein may be used in electronic devices such as, but not limited to, a head-mounted device (e.g., an electronic headset device, glasses, etc.) or another wearable device. Such head-mounted devices are referred to herein as “headsets” and may include extended reality headsets that allow users to view, create, consume, and share media content. In some examples, the headsets may include a display structure having a display which is placed over eyes of a user and allows the user to “see” the extended reality. As discussed further below, the term “extended reality” includes virtual reality, mixed reality, and/or augmented reality.

As used herein, the term “virtual environment” or “extended reality environment” refers to a simulated environment in which users can fully or partially immerse themselves. For example, an extended reality environment can comprise virtual reality (VR), augmented reality (AR), mixed reality, etc. An extended reality environment can include objects and elements with which a user can interact. In many cases, a user participates in an extended reality environment using a computing device, such as a dedicated extended reality device. As used herein, the term “extended reality device” refers to a computing device having extended reality capabilities and/or features (e.g., AR, VR, and/or mixed reality devices, other wearables, and/or another electronic device). In particular, an extended reality device can refer to a computing device that can include any device capable of presenting a full or partial extended reality environment.

More particularly, while examples of wearable electronic devices are provided above, it is to be understood that the flexible electronic systems described herein may be implemented in any type of electronic device including, but not limited to, mobile phones (e.g., cell phones, smart phones, etc.), tablet computing devices, electronic book reader devices, laptop or all-in-one computers, media players, portable gaming devices, televisions, monitors, cameras, wearable computing devices, electronic picture frames, audio virtual assistant devices, radios, speakers, personal computers, external hard drives, input/output devices (e.g., remote controls, game controllers, keyboards, mice, touch pads, microphones, speakers, etc.), and/or the like. Furthermore, the flexible electronic systems described herein may be implemented in electronic devices that include soft and/or flexible structures, such as apparel, gloves (e.g., haptic gloves), wrist wearables (e.g., fitness bands, watches, bracelets, etc.), rings, extended reality headsets (e.g., augmented reality and/or virtual reality headsets, which may be referred to herein simply as “headsets”), especially those having flexible headbands or straps, glasses, hats, neck wearables, shoes, clothing articles, or other wearable electronic devices.

In examples, the flexible electronic systems described herein may extend far beyond conventional/consumer electronics sectors and may have impact in human health monitoring and other therapeutics, human computer interfaces, etc.

### Example Flexible Electronic System Configurations

In some examples, a flexible electronic system may comprise a flexible substrate comprising an interlayer elastomer dielectric and a plurality of rigid components disposed within the flexible substrate, at least one rigid component comprising an electronic component. The flexible electronic system may further comprise a high-density interconnect region comprising one or more routing layers. In some examples, the flexible electronic system may further comprise a flexible barrier material fully or partially encapsulating the flexible electronic system.

In some examples, the flexible electronic system may further comprise a flexible interposer coupled to the flexible substrate and the barrier material. In examples, the flexible interposer may comprise one or more of polyamide, copper, or any other flexible and conductive material.

In some examples, the flexible substrate may comprise inhibited silicone. In some examples, the plurality of rigid components may comprise one or more of an integrated circuit, a surface mount device (SMD), or a flexible printed circuit (FPC).

In some examples the flexible electronic system and the high-density interconnect region may further comprise a plurality of routing layers and one or more through-vias. At least one through-via of the at least one or more through-vias may couple at least one of (i) two rigid components, (ii) two routing layers, or (iii) a rigid component and a routing layer. In examples, at least some of the routing layers may comprise conductive traces. In some examples, the conductive traces may comprise liquid metal. In some examples, the one or more through-vias may comprise at least one of plated copper, liquid metal, liquid metal-composite ink, a conductive composite, or a conductive adhesive.

In some examples, the flexible electronic system may further comprise a flexible ground plane and a flexible current collector.

In examples, a flexible electronic system may comprise a plurality of island regions, wherein each island region comprises a flexible substrate comprising an interlayer elastomer dielectric and a plurality of rigid components disposed within the flexible substrate. The flexible electronic system may further comprise a high-density interconnect region comprising one or more routing layers. In examples, at least some of the plurality of island regions may be arranged vertically above and/or overlapping another island region. In some examples, at least one of the plurality of island regions may be physically and/or electrically coupled to another island region.

In some examples, at least some adjacent island regions of the e plurality of island regions may be coupled together via one or more through-vias, wherein individual through-vias couple at least one of (i) two rigid components, (ii) two routing layers, or (iii) a rigid component and a routing layer. In examples, the one or more through-vias may comprise at least one of plated copper, liquid metal, liquid metal-composite ink, a conductive composite or a conductive adhesive.

In some examples, at least some of the plurality of island regions may be arranged laterally with respect to another island region. In examples, adjacent island regions of the at least some of the plurality of island regions may be coupled together via a flexible routing layer comprising one or more conductive traces. In some examples, the conductive traces may comprise liquid metal.

In some examples, a wearable device may comprise one or more flexible electronic systems as described above.

In examples, a method may comprise embedding two or more rigid components within a flexible substrate comprising an interlayer elastomer dielectric. The method may further comprise coupling two of the two or more rigid components via a routing layer within the flexible substrate and encapsulating the two or more rigid components and the flexible substrate with a barrier layer. In some examples, the method may further comprise coupling at least one flexible interposer to the flexible substrate and at least one flexible interposer to the barrier material. In examples, the method may comprise disposing a flexible ground plane on the flexible substrate within the barrier material and disposing a flexible current collector on the flexible substrate within the barrier material.

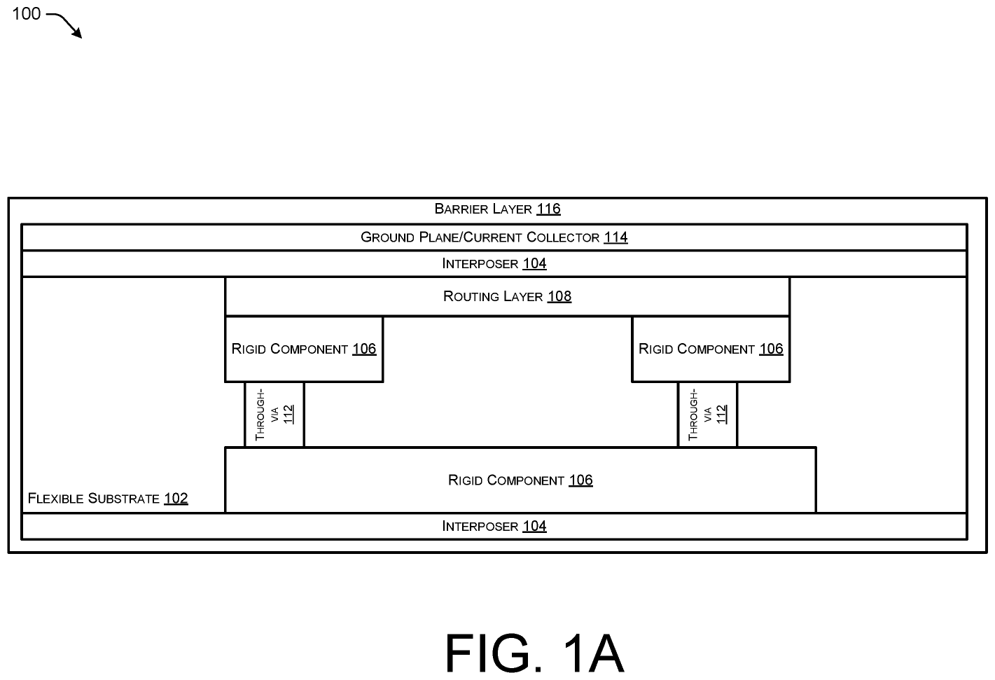

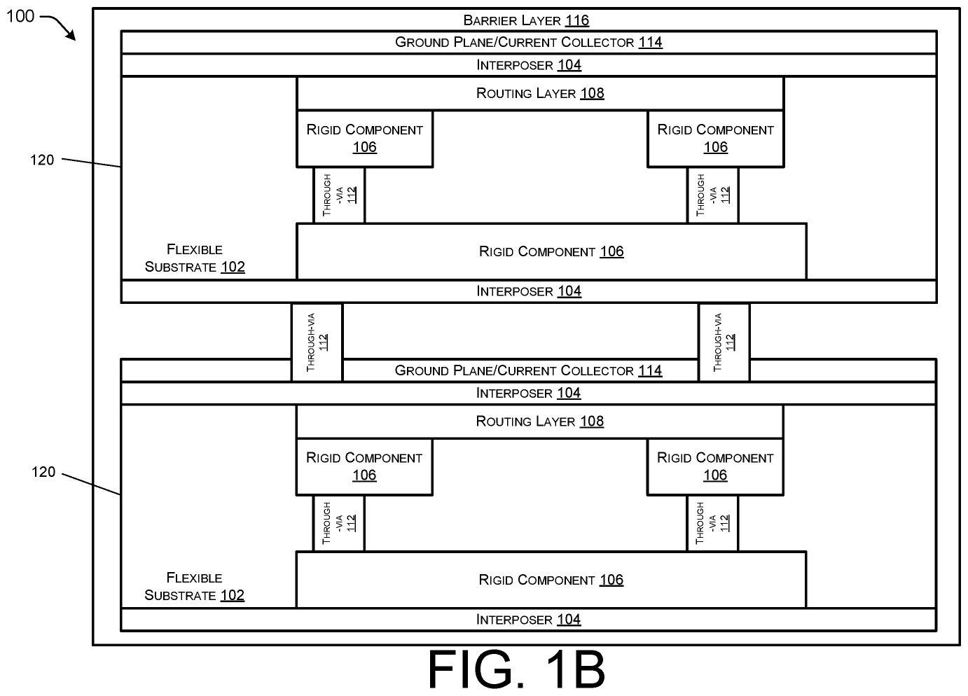

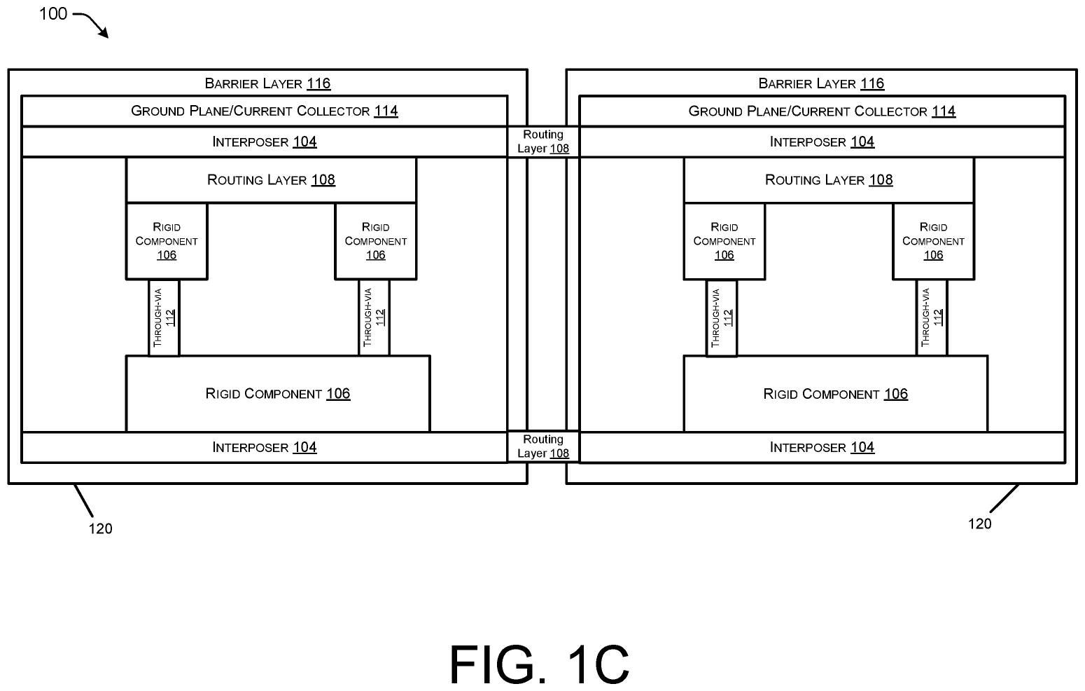

FIG. 1A schematically illustrates an example of a flexible electronic system 100. The flexible electronic system 100 includes a flexible and/or stretchable substrate 102 (flexible substrate 102). In examples, the flexible substrate 102 may comprise, for example, molded bluesil silicone, bluesil-EKJ interface, bluesil-component interface, etc.

The flexible electronic system 100 may further include high-density interposers 104 (or interconnects). The high-density interposers 104 may comprise, for example, Kapton EKJ, HN, ECD Cu, ENEPIG, etc. The flexible electronic system 100 may further include a plurality of rigid components 106 (or devices). The rigid components 106 may comprise, for example, surface mount devices (SMDs), valve arrays, pressure sensors, daisy chain SLE parts, control integrated circuits (ICs), etc. The rigid components 106 are embedded within the flexible substrate 102. The rigid components 106 may be coupled together via one or more routing layers 108 that include conductive traces 110. Additionally, one or more through-vias 112 may be utilized to couple the rigid components 106 to other rigid components 106 within the flexible electronic system 100. In examples, the flexible electronic system 100 includes one or more layers 114 configured as a ground plane or a current collector. In examples, the flexible electronic system 100 includes a barrier layer 116 that substantially encapsulates the components of the flexible electronic system 100. In some examples, the flexible electronic system 100 may have one or more portions that are not encapsulated (e.g., are exposed) to, for example, expose a sensor or speaker to the environment.

In examples, the rigid components 106 are embedded in the flexible substrate 102. By chemical manipulation (e.g., inhibited silicones), the bonding of stretchable elastomers to the rigid components (integrated circuits (ICs), surface mount devices (SMDs), and FPC regions may be enhanced, thereby circumventing common rigid-soft interfacial failures. In some examples, the flexible substrate 102 may also contain flexible and/or stretchable metal traces (not shown) for interconnections between the rigid components 106. In some examples, the metal traces (e.g., copper, silver, etc.) may be made stretchable by printing them on a stretched substrate and then releasing the stretched material thereby causing the trace to crepe (e.g., bunch up like an accordion) and then embedded or encapsulated in the flexible substrate 102.

As can be seen in FIG. 1B, individual flexible electronic systems 100 may be configured as rigid island regions 120 that may be coupled to other rigid island regions 120 arranged vertically above or below other rigid island regions 120 to provide a flexible electronic system 100 that includes multiple rigid island regions 120. The rigid island regions 120 may be coupled via through-vias 112 and/or routing layers 108 (not shown in FIG. 1B). In examples, the rigid island regions 120 may be formed by selectively disposing flexible printed circuit (FPC) materials (e.g., polyimide/copper, Ajinomoto build-up film (ABF)/Cu, or similar). In examples, the rigid island regions 120 may be referred to as high-density interconnects (HDIs) that enable fine pitch (or trace/space) line widths for electrical signal routing for chip-to-chip and SMD connections. The HDI is generally comprised of one or more routing layers 18 that may be vertically connected with conventional (e.g., plated copper) or unconventional conductive materials (e.g., liquid metals (LM), LM-composite inks, composites, conductive adhesives or similar materials) in the form of through-vias. Assembly of the HDIs may be conventional (e.g., solder) or unconventional (e.g., gold-to-gold interconnect (GGI), thermos-sonic bonding, adhesive bonding). Stacking of HDI layers above and below the flexible substrate 102 can be extended for one layer to a plurality of layers as needed to add system-level component densification.

As can be seen in FIG. 1C, rigid island regions 120 may be arranged laterally. Routing layers 108 may be utilized to couple adjacent rigid island regions. In some examples, through-vias 112, wiring techniques, etc. may be used in addition to or instead of the routing layers 108.

### Example Electronic Devices

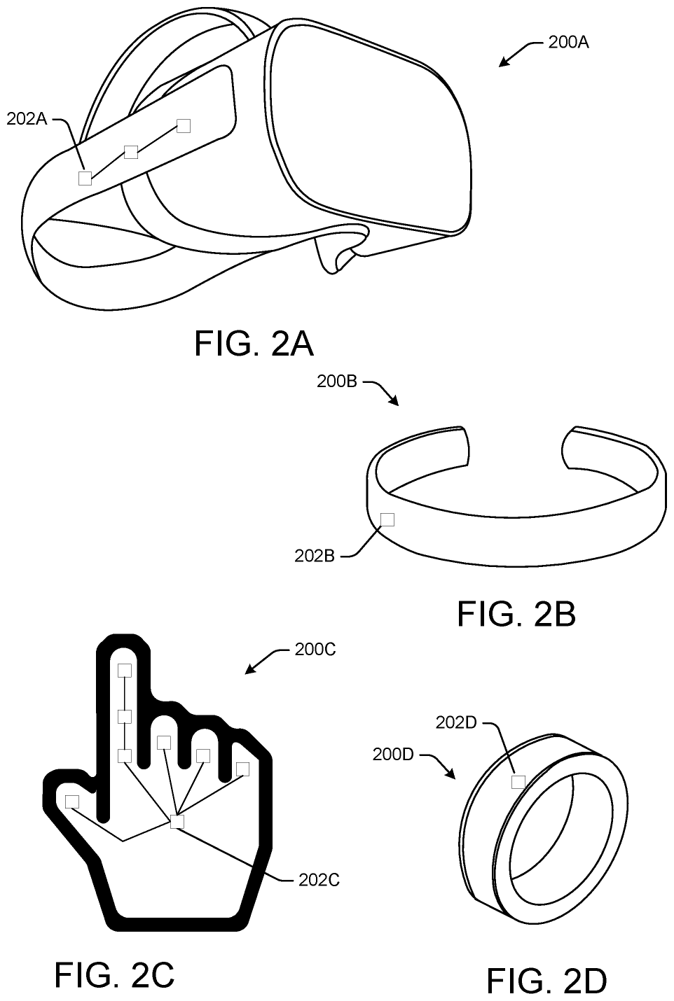

FIGS. 2A-2D illustrate schematic examples of electronic devices 200A-200D that include the flexible electronic systems 100 and rigid island regions 120 as shown and described in FIGS. 1A-1C. Each device is illustrated as including one or more flexible electronic systems 202A-202D, respectively. The one or more flexible electronic systems 202A-202D generally correspond to the example flexible electronic systems 100 described herein. In some examples, any of the wearable electronic devices 200A-200D may include multiple flexible electronic systems 100 and rigid island regions 120 according to this disclosure.

For example, a first electronic device 200A may include a head-mounted device such as an electronic headset device, glasses, or other head-mounted device. Such head-mounted devices are referred to herein as “headsets” and may include extended reality headsets that allow users to view, create, consume, and share media content. In some examples, the headsets may include a display structure having a display which is placed over eyes of a user and allows the user to “see” the extended reality. As discussed elsewhere in the application, the term “extended reality” includes virtual reality, mixed reality, and/or augmented reality. The first electronic device 200A may also include one or more flexible or compliant portions (e.g., one or more straps, headband, facial interface, and/or pads to engage a face or head of a user). In some examples, flexible electronic systems according to this disclosure may be incorporated into, coupled to, and/or may replace all or portions of these flexible and/or compliant portions of the headset or other wearable devices. In the example, of FIG. 2A, the first electronic device 200A includes multiple flexible electronic systems 202A that may be coupled by flexible routing, e.g., flexible routing layers or HDIs.

Furthermore, a second electronic device 200B may include a wrist-wearable device. Such a wrist-wearable device may include a watch, fitness tracker, bracelets, or other wrist-wearable devices.

A third electronic device 200C may include a soft and/or flexible wearable device including apparel, gloves, (e.g., haptic gloves), etc. In the example, of FIG. 2C, the third electronic device 200C includes multiple flexible electronic systems 202C that may be coupled by flexible routing, e.g., flexible routing layers or HDIs. A fourth electronic device 200D may include a ring or other jewelry type device.

### Example Processes

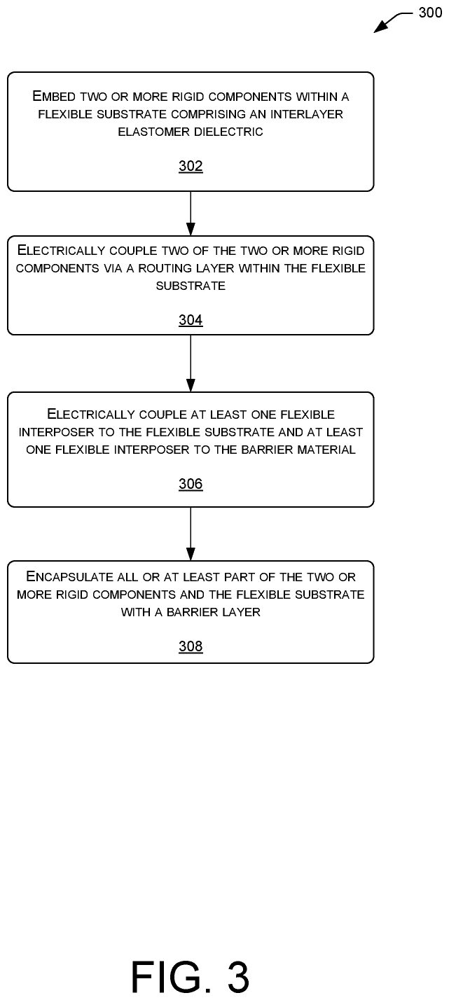

FIG. 3 illustrates a flow diagram of an example method 300 of forming a flexible electronic system 100. It should be appreciated that more or fewer operations might be performed than shown in FIG. 3 and described herein. These operations can also be performed in parallel, or in a different order than those described herein.

At 302, the method 300 includes embedding two or more rigid components within a flexible substrate comprising an interlayer elastomer dielectric. For example, the rigid components 106 may be embedded in the flexible substrate 102. By chemical manipulation (e.g., inhibited silicones), the bonding of stretchable elastomers to the rigid components (integrated circuits (ICs), surface mount devices (SMDs), and FPC regions may be enhanced, thereby circumventing common rigid-soft interfacial failures. In examples, the rigid components 106 may comprise, for example, surface mount devices (SMDs), valve arrays, pressure sensors, daisy chain SLE parts, control integrated circuits (ICs), etc. In some examples, the flexible substrate 102 may also contain flexible and/or stretchable traces (not shown) for interconnections between the rigid components 106.

At 304, the method 300 includes electrically coupling two of the two or more rigid components via a routing layer within the flexible substrate. For example, the rigid components 106 may be coupled together via routing layers 108 that include conductive traces 110. Additionally, through-vias 112 may be utilized to couple the rigid components 106 to other rigid components 106 within the flexible electronic system 100.

At 306, the method 1000 includes electrically coupling at least one flexible interposer to the flexible substrate and at least one flexible interposer to the barrier material. For example, the flexible electronic system 100 may further include high-density interposers 104 (or interconnects). The high-density interposers 104 may comprise, for example, Kapton EKJ, HN, ECD Cu, ENEPIG, etc. The flexible electronic system 100 may further include a plurality of rigid components 106 (or devices).

At 308, the method 300 includes encapsulating all or part of the two or more rigid components and the flexible substrate with a barrier layer. For example, the flexible electronic system 100 may include a barrier layer 116 that substantially encapsulates the components of the flexible electronic system 100.

### CONCLUSION

Although the discussion above sets forth example implementations of the described techniques and structural features, other architectures may be used to implement the described functionality and are intended to be within the scope of this disclosure. Furthermore, although the subject matter has been described in language specific to structural features and/or methodological acts, it is to be understood that the subject matter defined in the appended claims is not necessarily limited to the specific features or acts described. Rather, the specific features and acts are disclosed as exemplary forms of implementing the claims. For example, the structural features and/or methodological acts may be rearranged and/or combined with each other and/or other structural features and/or methodological acts. In various examples, one or more of the structural features and/or methodological acts may be omitted.

What is claimed is:

1. A flexible electronic system comprising a plurality of island regions, wherein at least one island region of the plurality of island regions comprises:
a flexible substrate comprising an interlayer elastomer dielectric;
a plurality of rigid components disposed within the flexible substrate, at least one rigid component comprising an electronic component; and
a high-density interconnect region comprising one or more routing layers electrically connected to the plurality of rigid components.

2. The flexible electronic system of claim 1, further comprising a flexible barrier material at least partially encapsulating the flexible electronic system.

3. The flexible electronic system of claim 2, further comprising:
a flexible interposer coupled to the flexible substrate and the flexible barrier material.

4. The flexible electronic system of claim 1, wherein the plurality of rigid components comprises one or more of an integrated circuit, a surface mount device (SMD), or a flexible printed circuit (FPC).

5. The flexible electronic system of claim 1, wherein the high-density interconnect region further comprises:
a plurality of routing layers; and
one or more through-vias, wherein at least one through-via of the one or more through-vias couples at least one of (i) two rigid components, (ii) two routing layers, or (iii) a rigid component and a routing layer.

6. The flexible electronic system of claim 5, wherein at least some of the routing layers comprise conductive traces.

7. The flexible electronic system of claim 1, further comprising:
a flexible ground plane; and
a flexible current collector.

8. The flexible electronic system of claim 1, wherein at least some of the plurality of island regions are arranged vertically above another island region.

9. The flexible electronic system of claim 8, wherein adjacent island regions of the at least some of the plurality of island regions are coupled together via one or more through-vias, wherein each through-via couples at least one of (i) two rigid components, (ii) two routing layers, or (iii) a rigid component and a routing layer.

10. The flexible electronic system of claim 1, wherein at least some of the plurality of island regions are arranged laterally with respect to another island region.

11. The flexible electronic system of claim 10, wherein adjacent island regions of the at least some of the plurality of island regions are coupled together via a flexible routing layer comprising one or more conductive traces.

12. A wearable device comprising a flexible electronic system comprising a plurality of island regions, wherein each island region comprises:
a flexible substrate comprising an interlayer elastomer dielectric;
a plurality of rigid components disposed within the flexible substrate, at least one rigid component comprising an electronic component; and
a high-density interconnect region comprising one or more routing layers electrically connected to the plurality of rigid components.

13. The wearable device of claim 12, further comprising a flexible barrier material at least partially encapsulating the flexible electronic system.

14. The wearable device of claim 13, further comprising:
a flexible interposer coupled to the flexible substrate and the barrier material.

15. The wearable device of claim 12, wherein the plurality of rigid components comprises one or more of an integrated circuit, a surface mount device (SMD), or a flexible printed circuit (FPC).

16. The wearable device of claim 12, wherein the high-density interconnect region further comprises:
a plurality of routing layers; and
one or more through-vias, wherein at least one through-via of the the one or more through-vias couples at least one of (i) two rigid components, (ii) two routing layers, or (iii) a rigid component and a routing layer.

17. The wearable device of claim 16, wherein at least some of the routing layers comprise conductive traces.

18. The wearable device of claim 12, further comprising:
a flexible ground plane; and
a flexible current collector.

19. The wearable device of claim 12, wherein:
at least some of the plurality of island regions are arranged vertically above another island region; and
adjacent island regions of the at least some of the plurality of island regions are coupled together via one or more through-vias, wherein each through-via couples at least one of (i) two rigid components, (ii) two routing layers, or (i) a rigid component and a routing layer.

20. The wearable device of claim 12, wherein:
at least some of the plurality of island regions are arranged laterally with respect to another island region; and
adjacent island regions of the at least some of the plurality of island regions are coupled together via a flexible routing layer comprising one or more conductive traces.
